(19) United States
(12) Patent Application Publication
(10) Pub. No.: US 2005/0052650 A1
(43) Pub. Date: Mar. 10, 2005

(54) System for high-resolution measurement of a magnetic field/gradient and its application to a magnetometer or gradiometer

(76) Inventor: Zhen Wu, New York, NY (US)

Correspondence Address: Diane Duun McKay, Esq.;Mathews, Collins, Shepherd & McKay, P.A., Suite 306, 100 Thanet Circle, Princeton, NJ, 08540, US

(21) Appl. No.: 10/933,637

(22) Filed: Sep. 3, 2004

Related U.S. Application Data
(60) Provisional application No. 60/500,245, filed on Sep. 5, 2003.
(60) Provisional application No. 60/502,945, filed on Sep. 16, 2003.

(51) Int. Cl. G01R 33/02

(52) U.S. Cl. 356/364

(57) ABSTRACT

The present invention relates to a method and system for high spatial resolution measurement of a magnetic field or gradient. The method determines Zeeman polarization at a submicron distance from cell surfaces of an optical pumping cell using two laser beams. A strong pump beam produces Zeeman polarization in the vicinity of surfaces inside the optical pumping cell. The Zeeman polarization precesses around the magnetic field that is to be measured and is probed by the evanescent wave of a weak probe beam. The precessing Zeeman polarization can be monitored by measuring reflectivity of the probe beam at an interface between the active medium and the cell. The polarization can be used to measure the magnetic field or gradient. In one embodiment a second probe beam in the yz-plane is incident on the same position as the pump beam and the first probe beam that is in the xz-plane. Both probe beams undergo total internal reflection at an interface between the cell surface and the active medium. The reflectivities of the two probe beams are measured, from which the x, y and z components of the magnetic field can be determined simultaneously.

### CROSS REFERENCE TO RELATED APPLICATION

This application claims the benefit of U.S. Provisional Patent Application No. 60/500,245 filed Sep. 5, 2003, the entirety of which is hereby incorporated by reference into this application; and U.S. Provisional Patent Application No. 60/502,945 filed Sep. 16, 2003, the entirety of which is hereby incorporated by reference into this application.

### BACKGROUND OF THE INVENTION

1. Field of the Invention

The present invention relates to a system for high spatial resolution measurement of a magnetic field/gradient, such as submicron spatial resolution and its application to a magnetometer or gradiometer.

2. Description of Related Art

The excitation of cells of atomic or molecular gases such as helium, rubidium or cesium, using a monochromatic light beam, is known and has been the object of a great many applications in many devices such as magnetometers. U.S. Pat. No. 5,503,708 describes a system for optical pumping of a cell of atomic or molecular gases having at least one resonance optical cavity containing a cell of atomic gases and a semiconductor laser generating an optical wave being coupled to the optical cavity.

U.S. Pat. No. 4,088,954 describes a magnetometer transducer which includes a group of plated magnetic wires arranged in parallel physically and connected in series electrically to serve as a drive circuit, and several turns of 0.025 mm diameter wire wound around the group of plated magnetic wires to serve as a sense coil. Each of the magnetic wires has a diameter of 0.05 mm with their centers being 0.25 mm apart. Because of its shape and small size, it is capable of spatial resolution of magnetic fields as low as 0.02 oe and it can make measurements of transverse magnetic fields as close as 0.08 mm from a surface.

Methods and systems for measuring brain activity have been described. When a neuron fires in the brain, a small current flows through the dendritic trunk, generating a tiny magnetic field, which, however, is far too weak to be measured. It often happens that tens of thousands of neurons are activated synchronously, and the superposition of the small currents produces a magnetic field outside the cranium that is measurable even though it is still extremely weak. By measuring these weak magnetic fields, one can obtain information not only about how the normal human brain functions, e.g., its response to various stimuli, such as sensory, auditory, and the like. Brain activity can be used to understand how the abnormal brain malfunctions. For example, the spatial and temporal information of the source of these magnetic fields can provide important information about epilepsy, Parkinson's disease, Schizophrenia, and other types of neural disorders.

Conventionally, mapping of the magnetic field outside the skull has been performed using Magnetoencephalography (MEG), which uses ultrasensitive superconducting quantum interference device (SQUID) detectors to measure the magnetic field as described in C. Del Gratta, V. Pizella, F. Tecchio and G. L. Romain, “Magnetoencephalography—a noninvasive brain imaging method with 1 ms time resolution”, Rep. Prog. Phys. 64:1759 (2001); and M. Hamalainen et al., “Magnetoencephalography—theory instrumentation, and applications to noninvasive studies of the working human brain”, Rev. Mod. Phys. 65:413 (1993). The method is completely noninvasive. It does not require the injection of any chemicals or exposure to X-rays or magnetic fields. Typically, MEG has spatial resolution of a few mm due to the finite size of the pick-up coil used in the SQUID detectors. MEG typically has temporal resolution on the order of 1 ms.

As described above, another technology of measuring magnetic fields is atomic magnetometers, which use spin polarized alkali metal vapor. The atomic magnetometers have achieved a sensitivity comparable to or better than the detection limit of SQUID detectors as described in D. Budker, D. F. Kimball, S. M. Rochester, V. V. Yashchuk, and M. Zolotorev, “Sensitive magnetometry based on nonlinear magneto-optical rotation”, Phys. Rev. A62:043403 (2000); and J. C. Allred, R. N. Lyman, T. W. Kornack and M. V. Romalis, “High-Sensitivity Atomic Magnetometer Unaffected by Spin-Exchange Relaxation”, Phy. Rev. Lett. 89:130801 (2002). Its temporal response or bandwidth, however, is typically not equivalent to the SQUID detectors. While a typical SQUID detector has a bandwidth of about 1 kHz, the bandwidth of atomic magnetometers is a few tens of Hz.

It is desirable to provide a system for high-resolution measurement of a magnetic field/gradient and measurement of three components of the magnetic field in X, Y and Z directions. Such a system can have applications in a magnetometer or gradiometer and in measuring brain activity.

### SUMMARY OF THE INVENTION

The present invention relates to a method and system for high spatial resolution measurement of a magnetic field or gradient. The method determines Zeeman polarization at a submicron distance from cell surfaces of an optical pumping cell using two laser beams. A strong pump beam produces Zeeman polarization in the vicinity of surfaces inside the optical pumping cell. This Zeeman polarization precesses around the magnetic field that is to be measured, causing one or more of the x, y and z components of the Zeeman polarization to oscillate. This oscillation of the Zeeman polarization is probed by the evanescent wave of a weak probe beam. The oscillation frequency of the Zeeman polarization, which determines the magnitude of the magnetic field, can be determined either by measuring the reflectivity of the probe beam at the interface between the active medium and the cell or by measuring the modulation of the polarization of the weak probe beam. Since the two methods have comparable signal-to-noise ratio, the present application concentrates on the first method of measuring the reflectivity of the probe beam.

In one embodiment of the present invention, a system for measurement of the magnetic field comprises a cell containing an active medium (e.g., alkali metal vapor). A pump beam tuned to transitions of atoms in the active medium provides optical pumping. The pump beam can be circularly polarized and incident perpendicularly on the cell surface in the z-direction. A probe beam in the xz-plane is incident at the same position on the surface of the cell as the pump beam and at an angle slightly larger than the critical angle. The probe beam undergoes total internal reflection at the interface between the cell surface and the active medium. The polarization of the probe beam is such that the evanescent wave of the probe beam is circularly polarized. The reflectivity of the probe beam is measured for determining the magnetic field.

In an alternate embodiment, a second probe beam in the yz-plane is incident on the same position as the pump beam and the first probe beam. The second probe beam undergoes total internal reflection at the interface between the cell surface and the active medium. The evanescent wave of the second probe beam is also circularly polarized. The reflectivities of the two probe beams are measured for determining the x, y, and z components of the magnetic field vector B simultaneously.

The system of the present invention can be used in medical imaging applications. In medical imaging applications, it is desirable to place the magnetometer to be very close to the skull since the magnetic field due to the brain activity is extremely weak. In conventional atomic magnetometers, the probe beam passes through the cell and the transmitted beam is monitored by a detector located on the other side of the cell. This geometric configuration makes it difficult to position the magnetometer very close to the skull. In the present invention, the reflected rather than the transmitted probe beam is monitored and consequently the probe beam and the detector are on the same side of the cell, which allows the magnetometer to be positioned very close to the skull.

The invention will be more fully described by reference to the following drawings.

### BRIEF DESCRIPTION OF THE DRAWINGS

FIG. 1 is a schematic diagram of an embodiment of a system for high spatial resolution measurement of a magnetic field or gradient in accordance with the teachings of the present invention.

FIG. 2 is a schematic of an alternate embodiment of system for high spatial resolution measurement of a magnetic field or gradient.

FIG. 3 is a schematic diagram of application of the present invention in a medical imaging application.

FIG. 4 is a graph of an attenuated total internal reflection signal S(v), illustrating the procedure of obtaining the reflectivity R.

FIG. 5 is a 2D image of the regionally specific ⁸⁵Rb hyperfine polarization.

### DETAILED DESCRIPTION

Reference will now be made in greater detail to a preferred embodiment of the invention, an example of which is illustrated in the accompanying drawings. Wherever possible, the same reference numerals will be used throughout the drawings and the description to refer to the same or like parts.

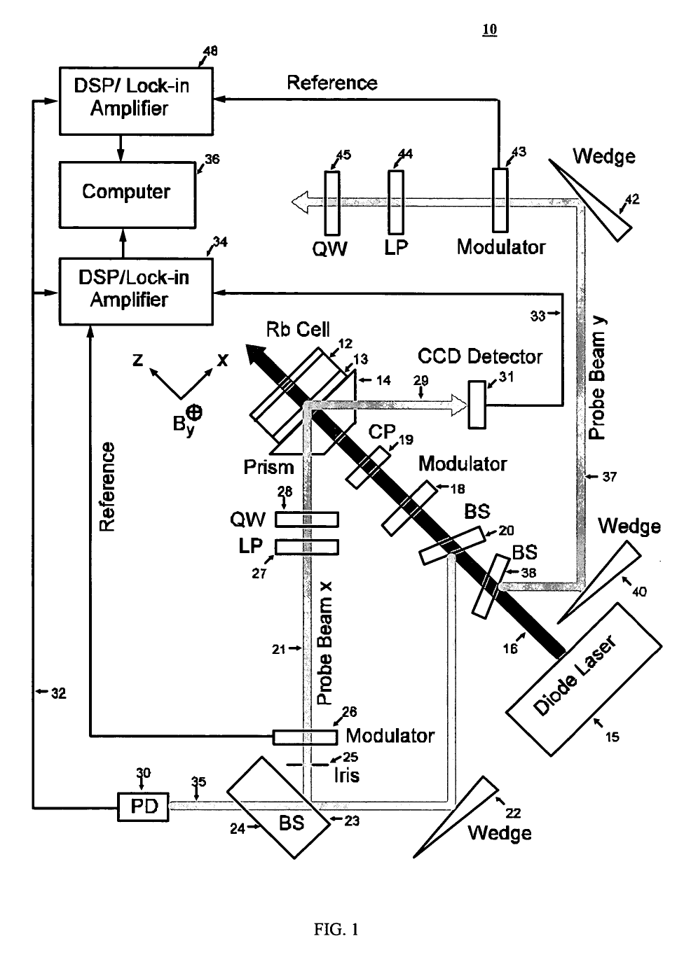

FIG. 1 is a schematic diagram of system for high spatial resolution measurement of magnetic field or gradient 10 in accordance with the teachings of the present invention. Cell 12 contains an active medium. For example, cell 12 can contain cesium (Cs), or rubidium (Rb) or potassium (K) vapor and buffer gas or gasses. In one embodiment, cell 12 can be a Pyrex glass cell filled with a ⁸⁷Rb isotope and about 100 Torr N₂ gas. For example, cell 12 can have a cylindrical shape. A typical cell 12 can have a diameter of about 10 mm and a height of about 1 mm. Cell 12 can be operated at about 150° C. to maintain sufficiently high number density of the active medium.

Cell 12 can be coated with anti-relaxation coatings (e.g., SurfaSil, siliconizing fluid). A procedure for coating the cells is described in X. Zeng, E. Miron, W. A. van Wijngaarden, D. Schreiber and W. Happer, “Wall relaxation of spin polarized ¹²⁹Xe nuclei”, Phys. Lett. 96A: 191 (1983), hereby incorporated by reference in its entirety into this application.

Prism 14 can be coupled to window 13 of cell 12. For example, prism 14 can be attached to window 13 using an index matching silicon fluid. Prism 14 can be a truncated fused quartz square pyramid prism.

Pump beam 16 produces optical pumping in cell 12. Pump beam 16 can be from a diode laser 15. Pump beam 16 from laser 15 is incident perpendicularly on a surface of cell 12 along the z direction. Pump beam 16 has a line width comparable to the D1 linewidth, which depends on the buffer gas density in the cell and is about 15 GHz for 100 Torr N₂. Pump beam 16 can be tuned to transitions of atoms in the active medium. For example, pump beam 16 can be tuned to D1 transitions of Rb atoms.

Pump beam 16 is modulated at an angular frequency ω_{P} either in its intensity or polarization. In one embodiment, modulator 18 can be used to modulate the intensity or polarization of pump beam 16. For example, such a modulator can be an electrooptic modulator, a chopper, or other devices. Circular polarizer (CP) 19 can be used to make pump beam 16 circularly polarized.

Pump beam splitter 20 (BS) can be placed within pump beam 16 for reflecting a small portion of laser light from pump beam 16 to form probe beam 21. For example, pump beam splitter 20 can be a glass plate. Probe beam 21 can be further attenuated to an intensity of several μW/cm² by reflection on wedge 22 and surface 23 of beam splitter (BS) 24. Probe beam 21 passes through iris 25. Iris 25 can be used to limit the size of probe beam 21 to have a size which is smaller than the size of pump beam 16 so that probe beam 21 is completely overlapped by pump beam 16. Probe beam 21 can be intensity modulated by modulator 26. Probe beam 21 can pass through linear polarizer (LP) 27 and quarter wave plate (QW) 28. The use of the combination of a linear polarizer (LP) 27 and a quarter wave plate (QW) 28 allows adjustment of ellipticity of probe beam 21 so to provide an evanescent wave which is circularly polarized. It is noted that if a circularly polarized incident probe beam is used, the evanescent wave would not be circularly polarized.

Probe beam 21 is in the xz plane. It is incident at the same position on window 13 of cell 12 as pump beam 16 and at an angle slightly larger than the critical angle \overline{θ}_{c}=sin⁻¹(1/n₁), where n₁ is the index of reflection of window 13. Accordingly, probe beam 21 undergoes total internal reflection at the interface between cell 12 and the active medium. The evanescent wave of probe beam 21 penetrates into the active medium a distance on the order of a micrometer, depending on the angle of incidence, and propagates along the x direction. Reflected probe beam 29 passes through prism 14 and is monitored by CCD detector 31.

To cancel laser intensity fluctuations, the intensity of reflected probe beam 29 and that of beam 35, which is proportional to the laser intensity, can be monitored respectively by charge coupled device (CCD) 31 and photodiode (PD) 30. Output 32 of photodiode 30 and output 33 of charge coupled device 31 can be fed into a digital signal processor (DSP)/lock-in amplifier 34 to yield a signal ratio S(v)=C₁R(v)/C₂, where C₁ and C₂ depend on the reflectivity and transmissivity of various optical components. R(v) is the reflectivity of the probe beam due to total internal reflection and v the frequency of the probe beam. The procedure of obtaining the reflectivity R(v) from the data is similar to that described in K. Zhao, Z. Wu, and H. M. Lai, “Optical determination of alkali metal vapor number density in the vicinity (˜10⁻⁵ cm) of cell surfaces”, J. Opt. Soc. Am. B18:12 (2001), hereby incorporated by reference in its entirety into this application.

Computer 36 receives output from DSP/lock in amplifier 34. Computer 36 can determine reflectivity of probe beam 21, from which one or more of the x, y, and z components of the magnetic field vector can be determined. Computer 36 can also generate images of the magnetic field.

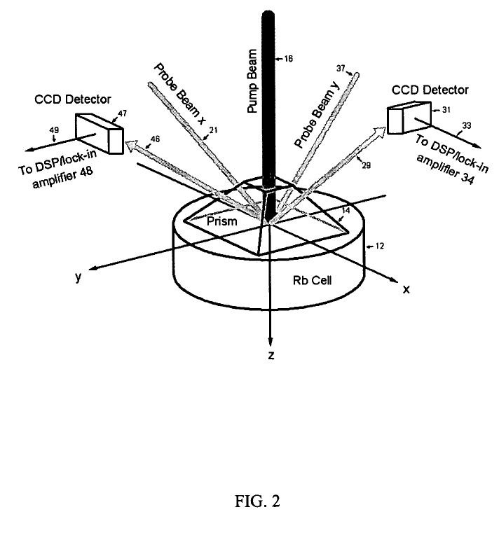

Probe beam (probe beam y) 37 from beam splitter (BS) 38 can be used in a dual-beam mode of operation of system 10, as described below. Modulator 43 modulates the intensity of probe beam 37. Probe beam 37 can pass through linear polarizer (LP) 44 and quarter wave plate (QW) 45 for adjustment of ellipticity of probe beam 37 to provide an evanescent wave which is circularly polarized. Probe beam 37 and probe beam 21 are directed to prism 14, as shown in FIG. 2. The intensity of reflected probe beam 46 can be monitored by charge coupled device (CCD) 47. Output 32 of photodiode 30 and output 49 of CCD 47 can be fed to DSP/lock-in amplifier 48 to yield a signal ratio, from which the reflectivity R for probe beam 37 can be obtained in the same fashion as for probe beam 21. Wedge 40 and wedge 42 direct probe beam 37 to modulator 43.

A single beam mode of operation of system 10 is suitable for the embodiment in which the magnetic field B=B_{y} is parallel to the y axis. Probe beam 21 is in the xz plane and its evanescent wave propagates along the x direction. Pump beam 16 is circularly polarized and creates a Zeeman polarization parallel to the z-axis. Probe beam 21 is elliptically polarized and its ellipticity can be adjusted so that its evanescent wave is circularly polarized. The reflectivity of a circularly polarized probe beam is given by
R=1−A(θ)(1−2<Sₓ>) (1)
where A(θ) is a function of the angle of incidence and <Sₓ>is the expectation value of Sₓ. Equation 1 relates the reflectivity R to the expectation value of Sₓ. Spin polarization vector <S> precesses around the magnetic field B_{y} in the xz-plane at the Larmor frequency

$${ω}_{L} = \frac{{eB}_{y}}{{m}_{e} c} \qquad ( 2 )$$

Where mₑ and e are the electron's mass and charge and c is the speed of light. The expectation value <Sₓ> is modulated at the Larmor frequency ω_{L} and the modulation frequency ω_{P} of pump beam 16, and so is the reflectivity R. The amplitude of this modulation exhibits a resonance when the modulation angular frequency ω_{P} of the pump beam is equal to the Larmor frequency
ω_{L}=ω_{P} (3)
Accordingly, equations (2) and (3) can be used to determine the value of the magnetic field B_{y}.

In an alternate embodiment, system 10 can be operated in a dual beam mode to determine the x, y, and z components of the magnetic field vector B simultaneously without any need to re-configure or re-orient system 10. Probe beam 21 and probe beam 37 are incident on a surface of cell 12 at the same position in cell 12 as pump beam 16 and at an angle slightly larger than the critical angle, and both undergo total internal reflection at the interface between the surface of cell 12 and the active medium. Probe beam 21 is in the xz-plane and probe beam 37 in the yz-plane. The evanescent wave of probe beam 21 propagates along the x-axis and the evanescent wave of probe beam 37 propagates along the y-axis. Probe beam 21 and probe beam 37 are polarized such that the corresponding evanescent waves are circularly polarized. The intensities of probe beam 21 and probe beam 37 are modulated by modulators 26 and 43, respectively. The reflectivities of probe beams 21 and probe beam 37 are obtained using DSP/lock-in amplifier 34 and DSP/lock-in amplifier 48. It is appreciated that since probe beam 21 and probe beam 37 are derived from pump beam 16 the relative intensities and frequency drift of probe beam 21 and probe beam 37 are automatically calibrated. The polar and azimuthal angles of the magnetic field vector B field are represented by θ and φ. The spin polarization <S> precesses around the B field at Larmor frequency and its Cartesian components are given by
<Sₓ>=S sin θ(cos φ cos θ cos ω_{L}t−sin φ sin ω_{L}t−cos φ cos θ) (4)
<S_{y}>=S sin θ(cos φ cos θ cos ω_{L}t−sin φ sin ω_{L}t−cos φ cos θ) (5)
<S_{z}>=S(sin² θ cos ω_{L}t+cos² θ) (6)
where S is the magnitude of <S>. The reflectivities obtained from equations (1), (4) and (5) comprise a dc part and a part oscillating at the angular frequency ω_{L}. The amplitudes of the oscillating part for probe beam x and probe beam y are respectively given by
Aₓ=Cₓ sin θ\sqrt{cos² φ cos² θ+sin² φ} (7)
A_{y}=C_{y} sin θ\sqrt{sin² φ cos² θ+cos² φ} (8)
where Cₓ and C_{y} are independent of θ and φ, and exhibit a resonance behavior when ω_{P}=ω_{L}, whence we obtain the magnitude of magnetic field B. The values of Cₓ and C_{y} can be calibrated using a known magnetic field oriented along a known direction, corresponding to θ=π/2 and φ=π/4. From equations (7) and (8) the amplitudes of the oscillating part of R for this calibration field are \overline{A}ₓ=Cₓ/\sqrt{2} and \overline{A}_{y}=C_{y}/\sqrt{2}. If the normalized amplitudes are defined as:

$$\begin{matrix}{a}_{x} = \frac{1}{\sqrt{2}} \frac{{A}_{x}}{{A}_{x}} & ( 9 ) \\ {a}_{y} = \frac{1}{\sqrt{2}} \frac{{A}_{y}}{{A}_{y}} & ( 10 )\end{matrix}$$

then
aₓ=sin θ\sqrt{cos² φ cos² θ+sin² φ} (11)
a_{y}=sin θ\sqrt{sin² φ cos² θ+cos² φ} (12)
Accordingly, equations (11) and (12) can be used to determine θ and φ of the B vector.

By expanding pump beam 16, probe beam 21 and probe beam 37 and using CCD area detectors 31 and 47, we can obtain 2D vector maps of the magnetic field in a single shot.

The spatial resolution of system 10 along the z-axis is determined by the penetration depth of probe beam 21. The fundamental limit of the spatial resolution in the xy-plane is due to the Goos-Hanchen effect and is on the order of the penetration depth. According to the Goos-Hanchen effect, the probe beam, which undergoes total internal reflection, travels in the active medium a distance on the order of the penetration depth. The spatial resolution in the xy-plane is also affected by the lateral diffusion of polarization, which blurs the boundary between regions of different polarizations. The spatial resolution limit due to this diffusion process in the Rb vapor is also on the order of the penetration depth. A suitable penetration depth can be in the range of 0.3 μm to 4.0 μm.

System 10 can operate as a magnetometer. Alternatively, system 10 can operate as a gradiometer. When the background magnetic field varies slowly spatially, system 10 as a gradiometer can be operated in a fashion similar to a conventional gradiometer. A differential output is measured between each pixel of the CCD area detector and a reference pixel of the CCD detector. This differential output will then be independent of the background magnetic field, which can be assumed to be the same at different pixels and therefore cancel each other in the differential output. If, however, the background magnetic field has large spatial gradient, for example it varies over a distance scale of 10⁻³ cm, the conventional way of operating a magnetometer as a gradiometer does not work since the pixel size is typically 25 μm and the background magnetic field at different pixels cannot be assumed to be the same. Because of the submicron spatial resolution of system 10 in the z direction, system 10 is particularly suitable to be operated as a gradiometer under these circumstances. One can measure the differential magnetic field at two positions z₁ and z₂ separated by a micron or less. For a miniature version of system 10, it may even be possible to have the system oscillate between the positions z₁ and z₂, thus allowing the use of a phase sensitive detection method.

The sensitivity of an atomic magnetometer is determined by the relaxation rate of the Zeeman polarization. In contrast to the conventional atomic magnetometers, where the optical path length of the probe beam is on the order of a centimeter, the probe beam(s) of system 10 only penetrate into the alkali metal vapor a distance of the order of a micron, resulting in an extremely short interaction time between the laser beam and the atoms. This effectively shortens the relaxation time of spin polarized alkali metal atoms, giving rise to transit time broadening of the resonance line. The transit time broadening can degrade the sensitivity of the magnetometer.

The adverse effect of the small penetration depth of the probe beam on the relaxation time or linewidth can be alleviated or eliminated by using the following methods. The thickness of cell 12 can be selected to be very thin. For example ultra thin cells, having a thickness on the order of about μm can be used in system 10. Furthermore, cell 12 can be coated with an anti-relaxation coating, such as silicone. In such coated thin cells the evanescent wave illuminates the entire region between the two opposing walls, which are separated by a distance on the order of μm, and the alkali metal atoms, which scatter back and forth between the two opposing walls, will stay in the evanescent wave for relatively long periods of time, thereby alleviating or eliminating transit time broadening. The scattering back and forth between the coated walls does not destroy the spin polarization of the alkali metal atoms.

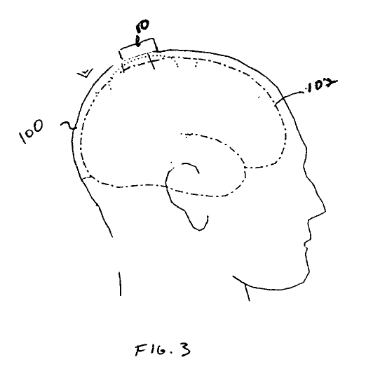

FIG. 3 is a schematic diagram of a system for measurement of a magnetic field or gradient in a biological object. System 10 is placed in the vicinity of skull 100. Dashed lines 102 denote the brain within skull 100. A plurality of systems 10 can be placed at various locations on skull 100. Alternatively, system 10 can be scanned over a plurality of portions of skull 100.

Unlike the magnetometers based on conventional SQUIDS, the system of the present invention has the advantage that it does not use cryogenic cooling which can have high manufacturing costs.

The present invention has the advantage that the use of a very thin layer of alkali metal vapor, of the thickness of a micrometer or less, allows miniaturization of the present invention, which will mitigate the inconvenience of a high operating temperature and allow the system 10 to be placed very close to the skull 100.

Alternatively, system 10 is placed in the vicinity of a heart of mammal. For example, system 10 can be placed in the vicinity of the chest.

The spatial resolution of the present invention allows the present invention to be suitable to measure magnetic fields that have a very large spatial gradient. For example, the present invention can measure magnetic fields that vary considerably over a distance on the order of about μm.

### EXPERIMENT

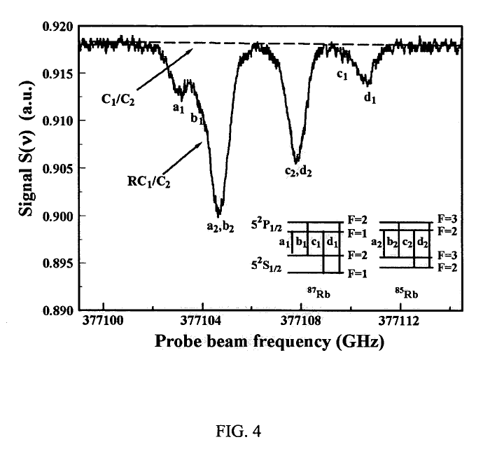

An experiment related to the present invention is described. Experimentally the main difference in the experiment is that hyperfine polarization is studied instead of Zeeman polarization. It is demonstrated that 2D images of Rb hyperfine polarization with submicron spatial resolution in the z direction can be obtained. Pyrex glass cells were used containing Rb of natural abundance (72.2% ⁸⁵Rb and 27.8% ⁸⁷Rb). The cells were filled with 5 Torr N₂ buffer gas. The cells were cylindrical having about 30 mm in diameter and 20 height. Free-running diode lasers, followed by Glan-Thompson linear polarizers with extinction ratio of about 10⁻⁵, provide p-polarized pump and probe beams. Both beams have a linewidth of 45 MHz. The cell temperature was 126° C. and Rb density 2.76×10¹³ cm⁻³. The probe beam is modulated by a chopper at 1900 Hz. The pump beam is tuned to transitions 5²S_{1/2}(F=2)→5²P_{1/2}(F′=2,3) and is incident perpendicularly on the cell surface. The line profiles of these two transitions overlap as a result of collisional and Doppler broadening. The pump beam depletes the population of the lower hyperfine level b of the ground state, causing an accumulation of the ⁸⁵Rb atoms in the upper hyperfine level a of the ground state. A weak probe beam, which is incident at the same spot where the pump beam is and at an angle slightly larger than the critical angle, undergoes total internal reflection at the interface between the glass surface and Rb vapor. The size of the probe beam is smaller than that of the pump beam. The intensity of the pump beam is 1.3 W/cm and that of the probe beam 6 μW/cm². The frequency of the probe beam is scanned across the Rb D1 line and its reflectivity R(v) is measured. The typical total internal reflection signal is shown in FIG. 4. The incidence angle of the probe beam corresponds to a penetration depth of 0.51 μm. The signal is averaged 10 times. The dashed line corresponds to no absorption and therefore is equal to C₁/C₂. The reflectivity R(v) is obtained by dividing the signal R(v)C₁/C₂ by the dashed line C₁/C₂. Hyperfine polarization <S·I> of ⁸⁵Rb atoms, where hS and hI (I=5/2) are respectively the spins of the electron and the nucleus, is a measure of the deviation of the populations of the Rb atoms in the two ground state hyperfine levels from their thermal equilibrium values. It is a given by

$$〈 S \cdot I 〉 = Tr ( S \cdot I ρ ) = \frac{I ( I + 1 )}{{N}_{a} + {N}_{b}} ( \frac{{N}_{a}}{{g}_{a}} - \frac{{N}_{b}}{{g}_{b}} ) \qquad ( 13 )$$

where ρ is the density operator of the ground state ⁸⁵Rb atom, Nₐ and N_{b} are respectively the populations of the ⁸⁵Rb ground state hyperfine multiplets of angular momenta a=I+1/2=3 and b=I−1/2=2, with gₐ=7 and g_{b}=5 being their respective statistical weights. When all of the ⁸⁵Rb atoms are in the hyperfine multiplet a, we have <S·I>=1.25.

According to eq. (13), the hyperfine polarization of ⁸⁵Rb atoms in the vicinity of cell surfaces is determined by the values of Nₐ and N_{b} near the surfaces, which can be deduced from the measured reflectivity of the probe beam. When the pump beam is off, the reflectivity R(v) is measured and fitted to the calculated one. The fitting parameters are Rb number density N and homogeneous linewidth y, which includes natural broadening, collisional broadening and the like. The best fit yields the values of N and y. When the pump beam is on, the number densities Nₐ and N_{b} of ⁸⁵Rb in the vicinity of cell surfaces are functions of the distance z from the surface due to surface interactions. If the dependence of Nₐ and N_{b} on z is ignored and Nₐ(z) and N_{b}(z) is replaced by their average values \overline{Nₐ} and \overline{N_{b}}, we can obtain the average hyperfine polarization \overline{<S·I>} by fitting R(v) to the calculated reflectivity with \overline{Nₐ} and \overline{N_{b}} as fitting parameters, using the same N and γ as determined when the pump beam is off. The z-dependence of the actual number densities Nₐ and N_{b} manifests itself in the dependence of the average hyperfine polarization \overline{<S·I>} on the penetration depth d or incidence angle θ of the probe beam. The penetration depth d is defined by

$$d = \frac{{λ}_{0}}{2 π {n}_{1}} \frac{1}{\sqrt{{sin}^{2} θ - 1 / {n}_{1}^{2}}}$$

where λ₀ is the wavelength of the beam in the vacuum.

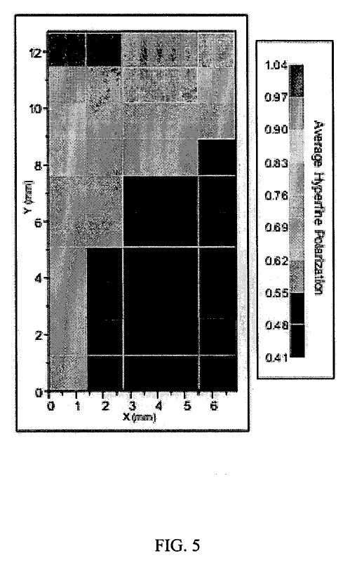

The mapping of the average ⁸⁵Rb hyperfine polarization \overline{<S·I>} at micron or sub-micron distance from the cell surfaces is demonstrated in FIG. 5, which shows a representative 2-D images of the ⁸⁵Rb hyperfine polarization at 1.4 micron distance from the cell surfaces in a damaged silicone-coated cell. The cell is intentionally damaged by high voltage discharge (a few tens of kV at 500 kHz), using a Tesla coil, which has a tip in the shape of a knife edge more or less parallel to the x-direction. The Rb density 2.9×10¹³ cm⁻³. The probe beam size is 1.2 mm×1.2 mm. The images are obtained by translating the stage on which the cell is mounted horizontally and vertically in a step size equal to that of the probe beam. The spatial resolution of the hyperfine polarization along the z-axis is determined by the penetration depth d of the probe beam.

It is to be understood that the above-described embodiments are illustrative of only a few of the many possible specific embodiments, which can represent applications of the principles of the invention. Numerous and varied other arrangements can be readily devised in accordance with these principles by those skilled in the art without departing from the spirit and scope of the invention.

1. A system for measurement of a magnetic field comprising:
a cell containing an active medium,
means for optical pumping of said cell with a pump beam tuned to transitions of atoms in said active medium;
means for applying a first probe beam to said cell to generate an evanescent wave in said cell which is incident at a same position in said cell as said pump beam; and
means for determining one or more components of said magnetic field by measuring reflectivity of said first probe beam at an interface between said active medium and said cell.

2. The system of claim 1 wherein said active medium is selected from the group consisting of a gas of alkali metal, a gas of cesium, a gas of rubidium and a gas of potassium.

3. The system of claim 1 wherein said pump beam is generated by a laser and said first probe beam is split from said pump beam with a first beam splitter.

4. The system of claim 1 further comprising:
a prism attached to said cell, said pump beam being applied perpendicularly through said prism to said cell in a z-direction and said first probe beam being applied in a xz-plane of said prism.

5. The system of claim 1 wherein said pump beam is circularly polarized.

6. The system of claim 5 wherein said evanescent wave generated by said first probe beam is circularly polarized.

7. The system of claim 1 further comprising:
means for adjusting ellipticity of said first probe beam for circularly polarizing said evanescent wave.

8. The system of claim 7 wherein said means for adjusting ellipticity of said first probe beam comprises:
a linear polarizer and a quarter wave plate.

9. The system of claim 1 further comprising means for modulating said pump beam at a frequency ω_{P} in its intensity or polarization.

10. The system of claim 9 wherein said means for modulating said pump beam comprises a modulator.

11. The system of claim 9 wherein said means for modulating said pumping beam is selected from an electrooptic modulator or a chopper.

12. The system of claim 1 wherein said first probe beam has a size which is smaller than a size of said pump beam.

13. The system of claim 12 further comprising an iris for limiting said size of said first probe to a size which is smaller than a size of said pump beam.

14. The system of claim 1 further comprising means for attenuation of intensity of said first probe beam.

15. The system of claim 14 wherein said means for attenuation of intensity of said first probe beam comprises:
a wedge for reflection of said pump beam after said first beam splitter and a second beam splitter receiving said reflection of said probe beam from said first beam splitter to split said probe beam.

16. The system of claim 1 further comprising:
means for modulating said first probe beam.

17. The system of claim 16 wherein said means for modulating said first probe beam comprises a modulator.

18. The system of claim 16 wherein said means for modulating said pumping beam is selected from an electrooptic modulator or a chopper.

19. The system of claim 1 wherein a spatial resolution of said system is on the order of the penetration depth of said first probe beam.

20. The system of claim 1-9 wherein said penetration depth is in a range of about 0.3 μm to about 4.0 μm.

21. The system of claim 19 wherein said spatial resolution is less than about 1 micron.

22. The system of claim 1 wherein said cell has a thickness on the order of about μm.

23. The system of claim 1 further comprising:
means for applying a second probe beam to said cell to generate an evanescent wave in said cell which is incident at a same position in said cell as said pump beam, wherein said first probe beam is in a xz-plane and said second probe beam is in a yz-plane.

24. The system of claim 23 wherein said pump beam is generated by a laser and said first probe beam is split from said pump beam with a first beam splitter and said second probe beam is split from said pump beam with a second beam splitter.

25. The system of claim 23 further comprising:
a prism attached to said cell, said pump beam being applied perpendicularly through a said prism to said cell in a z-direction and said first probe beam being applied in a xz-plane of said prism and said second probe beam being applied in a yz-plane of said prism.

26. The system of claim 23 wherein said pump beam is circularly polarized.

27. The system of claim 23 wherein said evanescent waves generated by said first probe beam and said second probe beam are circularly polarized.

28. The system of claim 23 further comprising:
means for adjusting ellipticity of said first probe beam for circularly polarizing said evanescent wave and means for adjusting ellipticity of said second probe beam for circularly polarizing said evanescent wave.

29. The system of claim 23 wherein said means for adjusting ellipticity of said first probe beam and means for adjusting ellipticity of said second probe beam comprises:
a linear polarizer and a quarter wave plate.

30. The system of claim 22 wherein said first probe beam and said second probe beam have a size which is smaller than a size of said pump beam.

31. The system of claim 23 further comprising:
means for attenuation of intensity of said first probe beam and said second probe beam.

32. The system of claim 1 further comprising:
means for modulating said first probe beam and means for modulating said second probe beam.

33. The system of claim 29 wherein said means for modulating said first probe beam and means for modulating said second probe beam comprises a modulator.

34. The system of claim 33 wherein said modulator is selected from an electrooptic modulator or a chopper.

35. The system of claim 1 wherein a spatial resolution of said system is on the order of penetration depth of said first probe beam and said second probe beam.

36. The system of claim 1 wherein said system operates as a magnetometer.

37. The system of claim 1 wherein said system operates as a gradiometer.

38. The system of claim 33 wherein said cell has a thickness on the order of about μm.

39. The system of claim 33 wherein x, y, and z, components of magnetic field are determined simultaneously without reconfiguring or re-orienting said system.

40. The system of claim 33 further comprising:
a first charge coupled device for monitoring intensity of a reflected first probe beam reflected at said interface between said active medium and said cell; and
a second charge coupled device for monitoring intensity of a reflected second probe beam reflected at said interface between said active medium and said cell.

41. The system of claim 40 further comprising:
means for generating images of said determined magnetic field from output of said first charge coupled device and said second charge coupled device.

42. The system of claim 41 wherein said image is a 2D vector map of said magnetic field.

43. The system of claim 42 wherein said 2D vector map is generated in a single shot.

44. A method for measurement of a magnetic field comprising the steps of:
optical pumping of a cell containing an active medium with a pump beam tuned to transitions of atoms in said active medium;
applying a first probe beam to said cell to generate an evanescent wave in said cell which is incident at a same position in said cell as said pump beam; and
determining one or more components in said magnetic field by measuring reflectivity of said first probe beam at an interface between said active medium and said cell.

45. The method of claim 44 wherein said active medium is selected from the group consisting of a gas of alkali metal, a gas of cesium, a gas of rubidium and a gas of potassium.

46. The method of claim 44 wherein said pump beam is circularly polarized.

47. The method of claim 44 wherein said evanescent wave generated by said first probe beam is circularly polarized.

48. The method of claim 44 further comprising the step of:
adjusting ellipticity of said first probe beam for circularly polarizing said evanescent wave.

49. The method of claim 44 further comprising the step of:
modulating said pump beam at a frequency ω_{P} in its intensity or polarization.

50. The method of claim 44 further comprising the step of:
limiting the size of said first probe beam to a size which is smaller than a size of said pump beam.

51. The method of claim 44 further comprising the step of:
attenuating intensity of said first probe beam.

52. The method of claim 44 further comprising the step of:
modulating said first probe beam.

53. The method of claim 44 having a spatial resolution on the order of the penetration depth of said first probe beam.

54. The method of claim 53 wherein said penetration depth is in a range of about 0.3 μm to about 4.0 μm.

55. The method of claim 53 wherein said spatial resolution is less than about 1 micron.

56. The method of claim 44 wherein said cell has a thickness on the order of about a micron.

57. The method of claim 44 further comprising the step of:
applying a second probe beam to said cell to generate an evanescent wave in said cell which is incident at a same position in said cell as said pump beam, wherein said first probe beam is in the xz-plane and said second probe beam is in the yz-plane.

58. The method of claim 57 wherein said pump beam is circularly polarized.

59. The method of claim 57 wherein said evanescent wave generated by said first probe beam and said second probe beam is circularly polarized.

60. The method of claim 57 further comprising the step of:
adjusting ellipticity of said first probe beam and said second probe beam for circularly polarizing said evanescent waves.

61. The method of claim 57 further comprising the step of:
limiting a size of said first probe beam and said second probe beam to a size which is smaller than a size of said pump beam.

62. The method of claim 57 further comprising the step of:
attenuating intensity of said first probe beam and said second probe beam.

63. The method of claim 57 further comprising the step of:
modulating said first probe beam and said second probe beam.

64. The method of claim 57 having a spatial resolution on the order of the penetration depth of said first probe beam and said second probe beam.

65. The method of claim 1 wherein said cell has a thickness on the order of about a micron.

66. The method of claim 57 wherein x, y, and z, components of magnetic field are determined simultaneously without reconfiguring or re-orienting said system.

67. The method of claim 57 further comprising:
monitoring intensity of said reflected first probe beam reflected at said interface between said active medium and said cell with a first charge coupled device; and
monitoring intensity of a reflected second probe beam reflected at said interface between said active medium and said cell with a second charge coupled device.

68. The method of claim 67 further comprising the step of:
generating images of said determined magnetic field from output of said first charge coupled device and said second charge coupled device.

69. The method of claim 69 wherein said image is a 2D vector map of said magnetic field.

70. The method of claim 69 wherein said 2D vector map is generated in a single shot.

71. A system for measurement of a magnetic field in a biological object comprising:
a cell containing an active medium;
means for optical pumping of said cell with a pump beam tuned to transitions of atoms in said active medium;
means for applying a first probe beam to said cell to generate an evanescent wave in said cell which is incident at a same position in said cell as said pump beam; and
means for determining one or more components of said magnetic field by measuring reflectivity of said first probe beam at an interface between said active medium and said cell.

72. The system of claim 71 wherein said biological system is a heart and said system is coupled to a chest of a mammal.

73. The system of claim 71 wherein said biological system is a brain and said system is coupled to a skull of a mammal.

74. The system of claim 71 further comprising:
means for applying a second probe beam to said cell to generate an evanescent wave in said cell which is incident at a same position in said cell as said pump beam, wherein said first probe beam is in a xz-plane and said second probe beam is in a yz-plane.
